(19) United States
(12) Patent Application Publication
(10) Pub. No.: US 2024/0332162 A1
(43) Pub. Date: Oct. 3, 2024

(54) ELECTRONIC DEVICE

(71) Applicant: STMicroelectronics International N.V., Geneva (CH)

(72) Inventors: William THIES, Quaix en Chartreuse (FR); Gilles GASIOT, Seyssinet-Pariset (FR); Andrea PAGANINI, Piacenza (IT); Jerome DEROO, Rives sur Fures (FR); Matteo REPOSSI, Pavia (IT)

(73) Assignee: STMicroelectronics International N.V., Geneva (CH)

(21) Appl. No.: 18/616,696

(22) Filed: Mar. 26, 2024

(30) Foreign Application Priority Data
Mar. 30, 2023 (FR) 2303078

(51) Int. Cl. H01L 23/522; H03H 7/01

(52) U.S. Cl. CPC H01L 23/5223; H01L 23/5225; H03H 7/0115

(57) ABSTRACT

A device includes a substrate and an interconnection network on the substrate. The interconnection network includes at least a first level, at least a second level and a third level. The first level includes one or more capacitors. The third level includes a metallic shield. The second level is positioned between the first level and the substrate. The capacitors of the first level are entirely separated from the substrate by the shield. The second level is located between the first and third levels.

### PRIORITY CLAIM

This application claims the priority benefit of French Application for Patent No. 2303078, filed on Mar. 30, 2023, the content of which is hereby incorporated by reference in its entirety to the maximum extent allowable by law.

### TECHNICAL FIELD

The present disclosure relates generally to electronic devices and, in particular, electronic devices comprising capacitors in the interconnection network, for example a Serializer/Deserializer or any device comprising a LC tank circuit.

### BACKGROUND

A Serializer/Deserializer (SerDes) is a pair of functional blocks commonly used in high speed communications to compensate for limited input/output. These blocks convert data between serial data and parallel interfaces in each direction. The primary use of a SerDes is to provide data transmission over a single line or a differential pair in order to minimize the number of I/O pins and interconnects.

An LC circuit, referred to as a tank circuit, is an electric circuit consisting of an inductor (L) and a capacitor (C) connected together. The circuit can act as an electrical resonator, storing energy oscillating at the circuit's resonant frequency. LC circuits are used either for generating signals at a particular frequency, for example clock or high speed signals, or picking out a signal at a particular frequency from a more complex signal; this function is called a bandpass filter. They are key components in many electronic devices, particularly radio equipment, used in circuits such as oscillators, filters, tuners and frequency mixers.

### SUMMARY

One embodiment provides a device comprising a substrate; an interconnection network on the substrate, the interconnection network comprising at least a first level, at least a second level and a third level, the first level comprising capacitors, the third level comprising a metallic shield, the second level being between the first level and the substrate, the capacitors of the first level being entirely separated from the substrate by the shield, the second level being between the first and third levels.

According to an embodiment, the interconnection network comprises an alternance of levels of metallization and intermediary layers, the levels of metallization comprising metal regions surrounded laterally by insulating regions, the intermediary layers comprising an insulating layer and vias extending through the insulating layer, the first, second and third layers being levels of metallization.

According to an embodiment, the third level is located between the second level and the substrate, and the second level is located between the first and the third level.

According to an embodiment, the shield is separated from the substrate by an intermediary layer.

According to an embodiment, the second level comprises only insulating material in regard to the capacitors of the first level.

According to an embodiment, the portions of the intermediary levels between the capacitors and the shield comprise only insulating material.

According to an embodiment, the capacitors and the shield are only separated by insulating materials.

According to an embodiment, the capacitors form a first region, the first region being surrounded by second region, no capacitors being located in the second region, the second region being separated from the substrate by the shield.

According to an embodiment, the width of the second region is at least 2 μm.

According to an embodiment, the third level is the level closest to the substrate among the levels of the interconnection network.

According to an embodiment, the capacitors are metal-oxide-metal capacitors.

According to an embodiment, the shield is configured to be polarized to a constant voltage.

According to an embodiment, the shield is configured to be polarized to the ground.

According to an embodiment, the device comprises a single second level.

According to an embodiment, the device comprises a serializer and/or a deserializer, at least part of the capacitors being part of the serializer and/or the deserializer.

According to an embodiment, the device comprises a LC tank, at least part of the capacitors being part of the LC tank circuit.

According to an embodiment, the shield is configured to be polarized to a low impedance voltage.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an example of a part of an electronic device;

FIG. 2 illustrates schematically an embodiment of an electronic device; and

FIG. 3 illustrates in more detail an example of implementation of the embodiment of FIG. 2.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

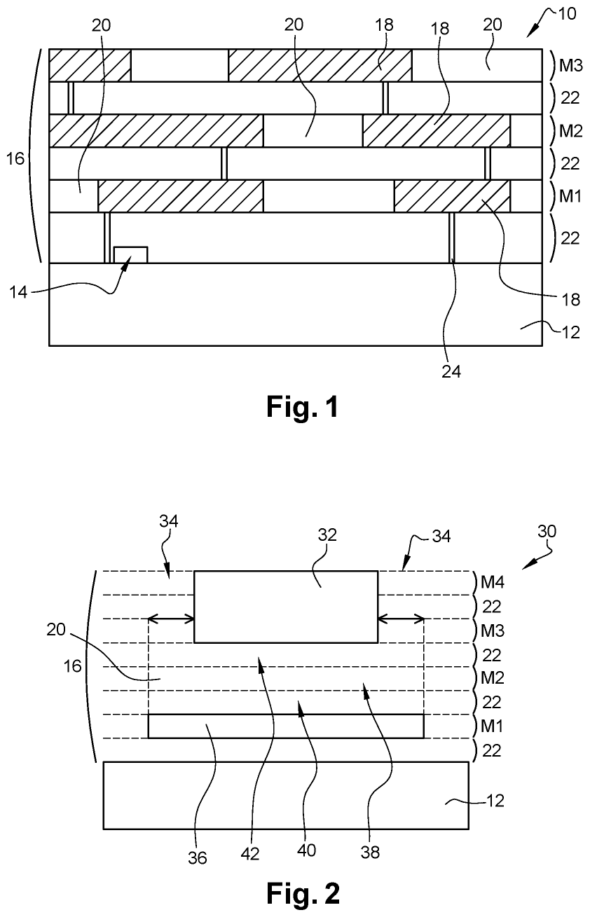

FIG. 1 illustrates an example of a part of an electronic device 10. The device 10 is, for example, an integrated circuit (IC) device.

The device 10 comprises a substrate 12. The substrate 12 is preferably made of a semiconductor material, for example of silicon. The substrate is, for example, a P-doped substrate.

The device 10 comprises, for example, electronic components formed in and/or on the substrate 12. The electronic components are, for example, transistors, resistors, diodes, capacitors. In the example of FIG. 1, a transistor 14 is located in and on the substrate 12. The transistor 14 is only represented by its gate with the substrate including, as known by those skilled in the art, doped regions forming the source and drain electrodes of the transistor.

The substrate is covered by an interconnection network 16. The network 16 comprises several levels of metallization. In the example of FIG. 1, only three levels M1, M2, M3 are represented. In practice, the network 16 can, for example, comprise at least two levels, for example between three to six levels.

The level M1 is the closest level to the substrate. The level M2 is above the level M1. In other words, the level M2 is the second closest level to the substrate. Therefore, the level M1 is between the level M2 and the substrate. The level M3 is above the levels M1 and M2. In other words, the level M3 is the third closest level to the substrate. Therefore, the levels M1 and M2 are between the level M3 and the substrate.

Each level comprises preferably a single layer. Each layer comprises metallizations 18, in other words metal regions 18, surrounded laterally by insulating regions 20, for example made of a silicon oxide material. The regions 18 of a level extend from the upper face of the level to the lower face of the level. In other words, the regions 18 extend on the entire height of said level. The regions 18 are, for example, made of copper or tungsten.

Each level is separated from the level, or the substrate, located below by an intermediary insulating layer 22, for example made of silicon oxide. In other words, the level M1 is separated from the substrate by a layer 22. The level M2 is separated from the level M1 by a layer 22. The level M3 is separated from the level M2 by a layer 22. The interconnection network 16 is therefore a stack of layers comprising an alternance of layers 22 and of levels of metallization M1, M2, M3, the lower layer of the stack preferably being a layer 22, the higher layer of the stack being preferably a level of metallization.

Each layer 22 comprises, for example, vias 24. The vias 24 of a layer 22 extend through said layer 22. In other words, each via 24 extends from the upper face of the layer 22 to the lower face of the layer 22. The vias 24 of layers 22 located between two levels of metallization are preferably configured to connect a region 18 of each layer. In other words, the vias 24 of layers 22 located between two levels of metallization comprise a lower extremity in contact with the upper face of a region 18 and an upper extremity in contact with the lower face of another region 18.

The layer 22 located between the substrate and the level M1 comprises vias 22 extending between regions 18 in the level M1 and portions of the substrate. In other words, the vias of the layer 22 located between the substrate and the level M1 comprise a lower extremity in contact with the substrate and an upper extremity in contact with the lower face of a region 18 of the level M1.

The layer 22 located between the substrate and the level M1 may also comprise parts of components located in and on the substrate. In the example of FIG. 1, the gate of transistor 14 is located in the layer 22 between the substrate and the level M1.

FIG. 2 illustrates schematically an embodiment of an electronic device 30. The device 30 is, for example, an integrated circuit. The device 30 is, for example, an integrated circuit comprising a serializer and/or a deserializer. The device 30 is, for example, any type of device comprising capacitors. The device 30 is, for example, an LC tank circuit.

The device 30 comprises a substrate 12 and an interconnection network 16 as described in relation to FIG. 1. Therefore, the network 16 comprises, as described in relation with FIG. 1, alternate layers 22 and levels of metallization M1, M2, M3, the lower layer of the stack preferably being a layer 22, the higher layer of the stack being preferably a level of metallization. In the example of FIG. 2, a level M4 of the network 16 is represented.

Preferably, each level M1, M2, M3, M4 and each layer 22 is planar layer. In other words, the upper faces of the levels M1, M2, M3, M4 and of the layers 22 are planar and preferably parallel to each other. Similarly, the lower faces of the levels M1, M2, M3, M4 and of the layers 22 are planar and preferably parallel to each other and to the upper faces. The height of the levels and of the layer 22 are preferably constant.

Preferably, the heights of the levels, in other words the distances between the upper and lower face of each level, are increasing or constant as the distance to the substrate increase. In other words, the height of a given level is higher than, or equal to, the heights of the levels located between the given level and the substrate.

The device 30 comprises a region 32. The region 32 comprises a plurality of capacitors. The capacitors of the region 32 are preferably metal-oxide-metal (MOM) capacitors. The capacitors of the region 32 are, for example, part of the serializer or of the deserializer. For example, the region 32 comprises only capacitors, preferably only MOM capacitors. At least part of the capacitors are, for example, part of the serializer and/or the deserializer. At least part of the capacitors are, for example, part of the LC tank circuit.

The region 32 is located in the level M3 and/or in a level higher than the level M3. The region 32 is not located in the levels M1 or M2 or in the layers 22 located on either side of the levels M1, M2. In the example of FIG. 2, the region 32 is located in levels M3 and M4.

The region 32 is, for example, surrounded, for example laterally surrounded, by a region 34 wherein there is no capacitor. For example, the region 34 comprises no conductive elements, in particular no metallic elements. For example, the width of the region 34, in other words the distance between a lateral face of the region 32 and the closest extremity of the region 34, in other words the distance between a conductive element of the region 32 and the closest conductive element outside of the region 32, is at least 2 μm.

The level M1 comprises a shield 36. The shield 36 is a metallic layer, for example made of copper or tungsten. The shield 36 is, for example, a metal region 18 of the level M1, as described in relation with the FIG. 1. The shield 36 extends in regard of the entire region 32. In other words, the entire region 32, in particular every capacitor of the region 32, is separated from the substrate by the shield 36. In other words, the capacitor of the region 32 occupies a first area in a plane parallel to the upper surface of the substrate, the shield 36 occupies a second area in a plane parallel to the upper surface of the substrate that is larger than the first area, and in a vertical alignment perpendicular to first and second planes (as well as perpendicular to the upper surface of the substrate) the shield 36 is positioned between the capacitor of the region 32 and the substrate.

The shield 36 is preferably polarized (i.e., electrically biased) at a reference voltage. The shield 36 is preferably polarized at a constant voltage. The shield 36 is preferably polarized at the ground level. Preferably, the shield 36 is polarized at a voltage of a low impedance. Alternatively, the shield 36 can be floating.

The shield is, for example, a continuous metal body or sheet. In other words, the shield, for example, does not comprise any openings in regard of the region 32.

The shield 36, for example, also extends in regard of the region 34, preferably the entire region 34. In other words, the horizontal dimensions of the shield 36 (i.e., the second area occupied by the shield), in other words the dimensions in the plane of the upper face of the level M1, are greater than the greatest horizontal dimensions of the region 32 (i.e., the first area occupied by the capacitor(s)).

The portion 38 of the level M2 located in regard of the shield 36 is preferably empty of conductive region. In other words, the portion 38 preferably comprises only insulating material, for example only an insulating region 20 as described in relation with FIG. 1. The level M2 corresponds to an intermediary level.

Similarly, the portions 40 and 42 of the layers 22 respectively between the levels M1 and M2 and between the levels M2 and M3 are preferably empty of conductive region. In other words, the portions 40 and 42 of the layers 22 respectively between the levels M1 and M2 and between the levels M2 and M3 preferably comprise only insulating material, for example only an insulating region 20 as described in relation with FIG. 1.

Preferably, the region 32 and the shield 36 are only separated by insulating material.

Alternatively, the structure of FIG. 2 can be located at higher levels than the levels described in relation with FIG. 2. For example, the shield 36 can be located in a level MX, X being an integer number higher than, or equal to, one. In the example of FIG. 2, the value of X is one. The region 32 comprising the capacitors is, for example, in levels MX+2 and/or higher. The structure comprises at least one intermediary level, at least the level MX+1, between the shield and the region 32, which corresponds to the level M2 in the example of FIG. 2, and which does not comprise any capacitor.

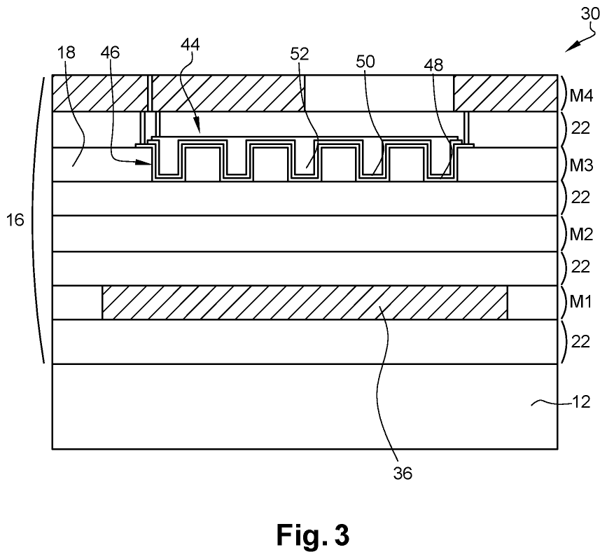

FIG. 3 illustrates in more detail an example of implementation of the device 30 of FIG. 2. The device 30 is, for example, an integrated circuit. The device 30 is, for example, an integrated circuit comprising a serializer and/or a deserializer. The device 30 is, for example, any type of device comprising capacitors.

The device 30 comprises the elements described in relation with FIG. 2. The device 30 comprises a substrate 12 and an interconnection network 16 as described in relation to FIG. 1. Therefore, the network 16 comprises, as described in relation with FIG. 1, an alternating of layers 22 and levels of metallization M1, M2, M3, the lower layer of the stack preferably being a layer 22, the higher layer of the stack being preferably a level of metallization.

FIG. 3 represents in more details the region 32. The region 32 comprises a plurality of capacitors 44. The capacitors 44 of the region 32 are preferably metal-oxide-metal (MOM) capacitors. To simplify the representation of FIG. 3, only one capacitor 44 is represented.

The level M3, wherein the capacitor 44 is located, comprises cavities 46 in the region 18. The cavities extend, for example, through the region 18 and reach the upper face of the layer 22.

The capacitor 44 comprises stack of a conductive layer 48, an insulating layer 50 and a conductive layer 52, the layer 50 being located between the layers 48 and 52.

Alternatively, any type of MOM capacitor can be located in the region 32.

It is possible to have not included a shield. However, the device 30 would then be significantly more sensitive to radiation, in particular heavy ion radiation. Indeed, carriers are deposited by the radiation and electrons are recombined in p-doped regions, for example in the p-doped substrate, at a faster rate than the holes. This phenomenon leaves excess holes during several microseconds, which is quite long, in the wavelength considered. This excess of holes modifies the value of the parasitic metal-oxide-semiconductor (MOS) capacitors. The capacitance changes approximately by 0.2%, which is enough to have a significant impact, in particular in a serializer and/or a deserializer or in a LC tank circuit. More precisely, such change is enough to generate a frequency drift in a phase locked loop (PLL), for example in the PLL of the serializer and/or deserializer.

It could have chosen not to separate the capacitors from the shield by a level. However, such structure would generate a high parasitic capacitance between the capacitors and the shield.

An advantage of the described embodiments is that under heavy ion testing the structure shows a reduction by at least 200 in the number of errors in comparison with a structure which does not comprise a shield.

Another advantage of the described embodiments is that the structure shows, during testing, a division by twenty of the parasitic capacitances due to carriers in comparison with a structure which does not comprise the intermediary level.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A device, comprising:
a substrate;
an interconnection network on the substrate, the interconnection network comprising a first level, a second level and a third level, the first level comprising one or more capacitors, the third level comprising a metallic shield, the second level being between the first level and the substrate, the one or more capacitors of the first level being entirely separated from the substrate by the shield, the second level being between the first and third levels.

2. The device according to claim 1, wherein the interconnection network comprises alternating levels of metallization and intermediary layers, the levels of metallization comprising metal regions surrounded laterally by insulating regions, the intermediary layers comprising an insulating layer and vias extending through the insulating layer, the first, second and third levels being levels of metallization.

3. The device according to claim 1, wherein the third level is located between the second level and the substrate.

4. The device according to claim 3, wherein the metallic shield is separated from the substrate by an intermediary layer.

5. The device according to claim 1, wherein the second level comprises only insulating material in regard to the one or more capacitors of the first level.

6. The device according to claim 1, wherein the portions of the intermediary levels between the one or more capacitors and the metallic shield comprises only insulating material.

7. The device according to claim 1, wherein the one or more capacitors and the metallic shield are only separated by insulating materials.

8. The device according to claim 1, wherein the one or more capacitors form a first region, the first region being surrounded by second region, no capacitors being located in the second region, the second region being separated from the substrate by the metallic shield.

9. The device according to claim 1, wherein a width of the second region is at least 2 μm.

10. The device according to claim 1, wherein the third level is the level closest to the substrate among the levels of the interconnection network.

11. The device according to claim 1, wherein the one or more capacitors are metal-oxide-metal capacitors.

12. The device according to claim 1, wherein the metallic shield is configured to be polarized to a constant voltage.

13. The device according to claim 1, wherein the metallic shield is configured to be polarized to the ground.

14. The device according to claim 1, wherein the metallic device comprises a single second level.

15. The device according to claim 1, wherein the device comprises a serializer and/or a deserializer, at least part of the one or more capacitors being part of the serializer and/or the deserializer.

16. The device according to claim 1, wherein the device comprises a LC tank circuit, at least part of the one or more capacitors being part of the LC tank circuit.

17. The device according to claim 1, wherein the metallic shield is configured to be polarized to a low impedance voltage.

18. A device, comprising:
a substrate;
an interconnection network on the substrate, the interconnection network comprising a first level, a second level and a third level;
a capacitor arranged in the first level, said capacitor occupying a first area in a plane parallel to an upper surface of the substrate;
a metallic shield arranged in the third level, said metallic shield occupying a second area in a plane parallel to the upper surface of the substrate, said second area being larger than the first area;
wherein the second level is located between the first level and the substrate;
wherein the second level is located between the first and third levels; and
wherein in a vertical alignment perpendicular to first and second planes the metallic shield is positioned between the capacitor and the substrate.

19. The device of claim 18, wherein a region of the second level located between the metallic shield and the capacitor does not include any metal structures.

20. The device of claim 18, wherein an insulating material region of the first level surrounds the capacitor, and wherein that insulating material region of the first level is separated, in the vertical alignment perpendicular to first and second planes, from the substrate by the metallic shield.

21. The device of claim 18, wherein the metallic shield is a continuous metal body.
